(19) United States
(12) Patent Application Publication
(10) Pub. No.: US 2018/0183428 A1
(43) Pub. Date: Jun. 28, 2018

(54) POWER HOLDING CIRCUIT DEVICE

(71) Applicant: Industrial Technology Research Institute, Hsinchu (TW)

(72) Inventors: Yu-Long Wang, Hsinchu (TW); Hsieh-Tai Su, Hsinchu (TW)

(21) Appl. No.: 15/845,403

(22) Filed: Dec. 18, 2017

(30) Foreign Application Priority Data
Dec. 23, 2016 (TW) 105142968

(51) Int. Cl. H03K 17/082; H02H 5/04; H02J 7/00; B60L 11/18; H02J 7/14; H02J 7/34; B60R 16/03

(52) U.S. Cl. CPC H03K 17/0822; H02H 5/044; H02J 7/0031; B60R 16/03; H02J 7/1461; H02J 7/345; B60L 11/1805

(57) ABSTRACT

A power holding circuit device adapted for a vehicle microcontroller unit (MCU), a car battery, and an ignition switch (IGN) comprises a metal-oxide-semiconductor field-effect transistor (MOSFET) switch unit, wherein the MOSFET switch unit is connected to the car battery; a first bipolar junction transistor (BJT), wherein the first BJT is connected to the MOSFET switch unit and the ignition switch; and a second bipolar junction transistor (BJT), wherein the second BJT is connected to the MOSFET switch unit and the vehicle MCU.

### CROSS REFERENCE TO RELATED APPLICATION

This application claims the priority benefits of Taiwan application No. 105142968, entitled “POWER HOLDING CIRCUIT DEVICE”, and filed on Dec. 23, 2016. The entirety of which is incorporated by reference herein.

### TECHNICAL FIELD

The present disclosure relates to a power holding circuit device, which cooperates with such as metal-oxide-semiconductor field-effect transistors (MOSFETs) and bipolar junction transistors (BJTs) and so on.

### BACKGROUND

In response to the trend towards smart and electronic vehicles, managing functions of a vehicle microcontroller unit (MCU), such as the functions for managing in-car electronic devices and recording driving data, are getting more and more important.

The power supplies of vehicle MCUs are typically sourced from car batteries and turned on or off by using an ignition switch (IGN). However, when the vehicle is powered down or signals of the vehicle are unstable without any warning or accidentally, the power supplies of vehicle MCUs output from the car batteries will be suddenly cut off. At this moment, in addition to giving the driver abnormal sense, there is no enough time for the vehicle MCUs to process the data and resulting in the data loss. Further, if other internal system components of the vehicle are shut down without warning or accidentally, this may also lead to the deterioration of the vehicle MCUs, or to reduce the lifetime of the vehicle MCUs.

Therefore, in order to prevent the vehicle microcontroller from failing to process data in the event of an accidental power failure, how to solve the problem of the deterioration of the vehicle MCUs caused by the abnormal power-down and how to protect the data due to the abnormal power-down become issues that the industry is trying to solve.

### SUMMARY

The present disclosure provides a power holding circuit device adapted for a vehicle microcontroller unit (MCU), a car battery, and an ignition switch (IGN).

In an embodiment of the present disclosure, the power holding circuit device comprises a metal-oxide-semiconductor field-effect transistor (MOSFET) switch unit, connected to the car battery; a first bipolar junction transistor (BJT), connected to the MOSFET switch unit and the ignition switch; and a second bipolar junction transistor (BJT), connected to the MOSFET switch unit and the vehicle MCU.

The foregoing will become better understood from a careful reading of a detailed description provided herein below with appropriate reference to the accompanying drawings.

### BRIEF DESCRIPTION OF THE DRAWINGS

FIG. 1 is a block diagram illustrating a power holding circuit device in accordance with an embodiment of the present disclosure.

FIG. 2 is a schematic circuit diagram illustrating a power holding circuit device in accordance with an embodiment of the present disclosure.

### DETAILED DESCRIPTION OF DISCLOSED EMBODIMENTS

Below, exemplary embodiments will be described in detail with reference to accompanying drawings so as to be easily realized by a person having ordinary knowledge in the art. The inventive concept may be embodied in various forms without being limited to the exemplary embodiments set forth herein. Descriptions of well-known parts are omitted for clarity, and like reference numerals refer to like elements throughout.

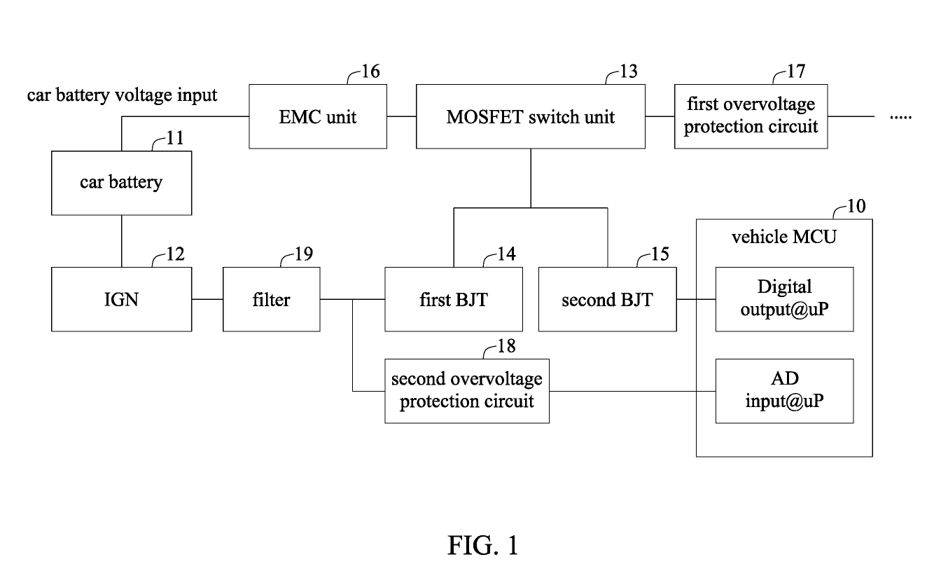

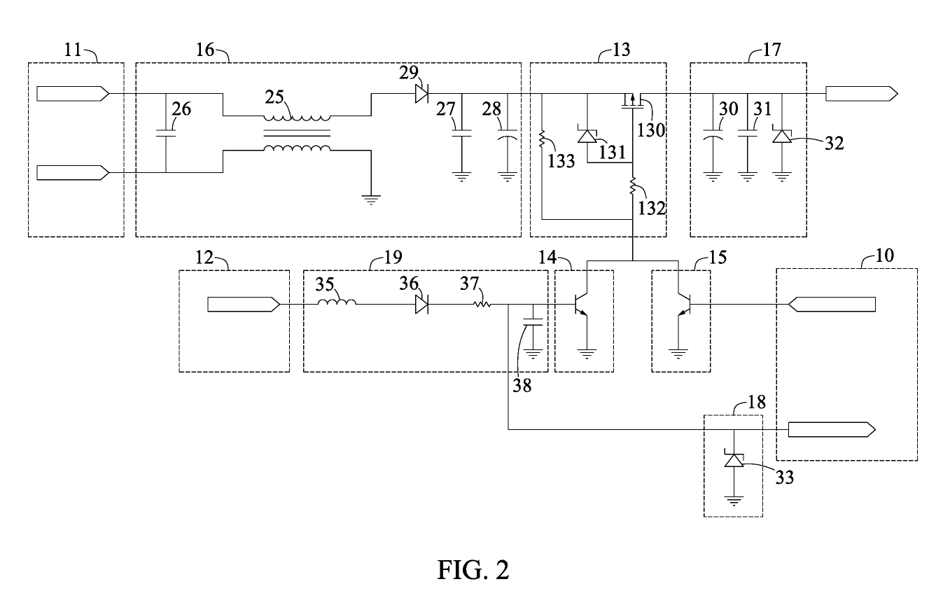

FIG. 1 is a block diagram illustrating a power holding circuit device in accordance with an embodiment of the present disclosure, and FIG. 2 is a schematic circuit diagram illustrating a power holding circuit device in accordance with an embodiment of the present disclosure.

Referring to FIG. 1, the power holding circuit device of the present disclosure is adapted for a vehicle microcontroller unit (MCU) 10, a car battery 11, and an ignition switch (IGN) 12. In accordance with the embodiment of FIG. 1, the power holding circuit device at least comprises a metal-oxide-semiconductor field-effect transistor (MOSFET) switch unit 13, a first bipolar junction transistor (BJT) 14, and a second bipolar junction transistor (BJT) 15.

Please be noted that, according to actual requirements, the power holding circuit device disclosed in the present disclosure may flexibly choose whether an electromagnetic compatibility (EMC) unit 16, a first overvoltage protection circuit 17, a second overvoltage protection circuit 18, or a filter 19 is adapted or not. In other words, at least one of the EMC unit 16, the first overvoltage protection circuit 17, the second overvoltage protection circuit 18, and the filter 19 may be further included in the power holding circuit device, and this may depend on the actual requirements.

The MOSFET switch unit 13 is connected to the car battery 11. In this embodiment, the MOSFET switch unit 13 may be, but not limited to a p-channel MOSFET 130, a Zener diode 131 bridged between a gate terminal and a source terminal of the p-channel MOSFET 130, and a plurality of resistors 132 and 133 connected to the Zener diode 131.

The first BJT 14 is connected to the MOSFET switch unit 13 and the ignition switch 12. The second BJT 15 is connected to the MOSFET switch unit 13 and the vehicle MCU 10. In this embodiment, the first BJT 14 and the second BJT 15 are both n-p-n type transistors, wherein a collector terminal of the first BJT 14 and a collector terminal of second BJT 15 both connect to the gate terminal of the p-channel MOSFET 130.

In this embodiment, a base terminal of the first BJT 14 connects to the ignition switch 12. An emitter terminal of the first BJT 14 is grounded. A base terminal of the second BJT 15 connects to the vehicle MCU 10. An emitter terminal of the second BJT 15 is grounded.

The electromagnetic compatibility (EMC) unit 16 is connected between the MOSFET switch unit 13 and the car battery 11. Referring to FIG. 2, the EMC unit 16 comprises an inductor 25, capacitors 26, 27 and 28, and a diode 29. An end of the inductor 25 connects to the capacitor 26. Another end of the inductor 25 and the diode 29 are connected in series. A cathode of the diode 29 connects to the capacitors 27 and 28. The capacitors 27 and 28 are connected in parallel.

The first overvoltage protection circuit 17 is connected to the MOSFET switch unit 13. Referring to FIG. 1, the first overvoltage protection circuit 17 comprises capacitors 30 and 31, and a Zener diode 32. The capacitors 30 and 31, and the Zener diode 32 are connected in parallel. The second overvoltage protection circuit 18 is connected to the vehicle MCU 10 and the first BJT 14. The second overvoltage protection circuit 18 comprises a Zener diode 33.

The filter 19 is connected between the first BJT 14 and the ignition switch 12. Referring to FIG. 1, the filter 19 comprises an inductor 35, a diode 36, a resistor 37, and a capacitor 38. The inductor 35, the diode 36, and the resistor 37 are connected in series. An end of the capacitor 38 is grounded.

Since the MOSFET switch unit 13 comprises the p-channel MOSFET 130, a source terminal of the p-channel MOSFET 130 is coupled to the car battery 11. A gate terminal of the p-channel MOSFET 130 is coupled to the vehicle MCU 10. A drain terminal of the p-channel MOSFET 130 is coupled to the first overvoltage protection circuit 17. When the gate terminal of the p-channel MOSFET 130 is at a low level, the p-channel MOSFET 130 turns on so that the power supply of the car battery 11 flows into the vehicle MCU 10. When the gate terminal of the p-channel MOSFET 130 is at a high level, the p-channel MOSFET 130 turns off so that the power supply of the car battery 11 is cut off.

The first BJT 14 and the second BJT 15 are both n-p-n type transistors. Collectors of the first BJT 14 and the second BJT 15 both connect to the gate terminal of the p-channel MOSFET 130 through the resistor 132. A base terminal of the first BJT 14 connects to the ignition switch 12 and an input terminal of the vehicle MCU 10. A base terminal of the second BJT 15 connects to an output terminal of the vehicle MCU 10. Emitter terminals of the first BJT 14 and the second BJT 15 are grounded.

The functions of the first BJT 14 and the second BJT 15 are as follows. When the base terminal of one of the first BJT 14 or the second BJT 15 is at a high level, the first BJT 14 or the second BJT 15 will turn on so that its collector terminal and its emitter terminal are then grounded. At this moment, the first BJT 14 or the second BJT 15 works in a saturation region when turning on. However, when the base terminals of the first BJT 14 and the second BJT 15 are both at a low level, the first BJT 14 and the second BJT 15 will turn off. At this moment, the power supply of the car battery 11 will not enter the vehicle MCU 10.

In an operation of the vehicle MCU 10, when the vehicle MCU 10 determines that a voltage value of the ignition switch 12 is less than a minimum limit value, the vehicle MCU 10 enables the first BJT 14 to turn off. After that, when the vehicle MCU 10 is processing data, the vehicle MCU 10 sends out a voltage holding signal to turn on the second BJT 15. When the vehicle MCU 10 finishes the processing of the data, the vehicle MCU 10 enables the second BJT 15 to turn off. Wherein, when the vehicle MCU 10 determines that the voltage value of the ignition switch 12 is greater than the minimum limit value, the vehicle MCU 10 enables the first BJT 14 and the MOSFET switch unit 13 to turn on. So that when the vehicle MCU 10 is processing data, the vehicle MCU 10 further enables the second BJT 15 to turn on.

In an embodiment, the power holding circuit device of the present disclosure provides that the vehicle MCU 10 has the ability to continuously process data after an abnormal power failure accidentally or power instability. The power holding circuit device has the advantages of smaller circuit area and low manufacturing cost. The power holding circuit device can additionally connect to a plurality of power conversion ICs with different types and functions. The power holding circuit device sufficiently solves the problem of power supply security management for the vehicle MCU when the car battery accidentally fails.

It will be apparent to those skilled in the art that various modifications and variations can be made to the disclosed embodiments. It is intended that the specification and examples be considered as exemplary embodiments only, with a scope of the disclosure being indicated by the following claims and their equivalents.

What is claimed is:

1. A power holding circuit device adapted for a vehicle microcontroller unit (MCU), a car battery, and an ignition switch (IGN), comprising:
a metal-oxide-semiconductor field-effect transistor (MOSFET) switch unit connected to the car battery;
a first bipolar junction transistor (BJT) connected to the MOSFET switch unit and the ignition switch; and
a second bipolar junction transistor (BJT) connected to the MOSFET switch unit and the vehicle MCU.

2. The power holding circuit device according to claim 1, wherein when the vehicle MCU determines that a voltage value of the ignition switch is less than a minimum limit value, the vehicle MCU enables the first BJT to turn off; when the vehicle MCU is processing data, the vehicle MCU sends out a voltage holding signal to turn on the second BJT; when vehicle MCU finishes the processing of the data, the vehicle MCU enables the second BJT to turn off.

3. The power holding circuit device according to claim 1, wherein when the vehicle MCU determines that a voltage value of the ignition switch is greater than a minimum limit value, the vehicle MCU enables the first BJT and the MOSFET switch unit to turn on; when the vehicle MCU is processing data, the vehicle MCU enables the second BJT to turn on.

4. The power holding circuit device according to claim 1, wherein the MOSFET switch unit comprises:
a p-channel MOSFET;
a Zener diode bridged between a gate terminal and a source terminal of the p-channel MOSFET; and
a plurality of resistors connected to the Zener diode.

5. The power holding circuit device according to claim 4, wherein the first BJT and the second BJT are both n-p-n type transistors, and a collector terminal of the first BJT and a collector terminal of the second BJT both connect to the gate terminal of the p-channel MOSFET.

6. The power holding circuit device according to claim 1, wherein a base terminal of the first BJT connects to the ignition switch, and an emitter terminal of the first BJT is grounded.

7. The power holding circuit device according to claim 1, wherein a base terminal of the second BJT connects to the vehicle MCU, and an emitter terminal of the second BJT is grounded.

8. The power holding circuit device according to claim 1, further comprising:
an electromagnetic compatibility (EMC) unit connected between the MOSFET switch unit and the car battery.

9. The power holding circuit device according to claim 1, further comprising:
a first overvoltage protection circuit connected to the MOSFET switch unit.

10. The power holding circuit device according to claim 1, further comprising:
a second overvoltage protection circuit connected to the vehicle MCU and the first BJT.

11. The power holding circuit device according to claim 1, further comprising:
a filter connected between the first BJT and the ignition switch.
